(19) United States
(12) Patent Application Publication
(10) Pub. No.: US 2026/0044118 A1
(43) Pub. Date: Feb. 12, 2026

(54) TIME-TO-DIGITAL CONVERTER WITH SUB-100FS RESOLUTION AND BASED ON TRANSMISSION LINE STRUCTURE

(71) Applicant: SOUTH CHINA UNIVERSITY OF TECHNOLOGY, Guangzhou (CN)

(72) Inventors: Xiang YI, Guangzhou (CN); Kaiming ZHONG, Guangzhou (CN); Wenquan CHE, Guangzhou (CN); Quan XUE, Guangzhou (CN)

(73) Assignee: SOUTH CHINA UNIVERSITY OF TECHNOLOGY, Guangzhou (CN)

(21) Appl. No.: 18/995,862

(22) PCT Filed: Jul. 28, 2023
(86) PCT No.: PCT/CN2023/109935

§ 371 Date: Jan. 17, 2025

(30) Foreign Application Priority Data
Dec. 5, 2022 (CN) 202211549723.8

(51) Int. Cl. G04F 10/00; H03K 5/14; H03L 7/095; H03L 7/18; H03M 1/50

(52) U.S. Cl. CPC G04F 10/005; H03K 5/14; H03L 7/095; H03L 7/18; H03M 1/50

(57) ABSTRACT

A time-to-digital converter with a sub-100 fs resolution and based on a transmission line structure includes three-stage of time-to-digital converters (TDCs), where the three-stage of TDCs are connected in parallel; and a plurality of delay units are disposed for each stage of TDC, the delay unit is connected to a locking detector, and the locking detector determines an output result of each stage TDC and performs locking; two input signals first enter the first-stage TDC for being quantized, and based on an output result of a comparator, the locking detector determines that the first-stage TDC has been locked, and an output thereof is frozen; and determining TDC at the next stage is performed, and a phase difference between the two signals gradually decreases with the locking of a phase-locked loop, which means phase difference alignment is performed, and the phase-locked loop completes locking.

### CROSS REFERENCE TO THE RELATED APPLICATIONS

This application is the national phase entry of International Application No. PCT/CN2023/109935, filed on Jul. 28, 2023, which is based upon and claims priority to Chinese Patent Application No. 202211549723.8, filed on Dec. 5, 2022, the entire contents of which are incorporated herein by reference.

### TECHNICAL FIELD

The present invention relates to a time-to-digital converter, and in particular to a time-to-digital converter with a sub-100 fs resolution and based on a transmission line structure.

### BACKGROUND

A digital radio frequency (RF) transceiver is a new type of transceiver architecture, which is developed by making full use of advantages of a digital circuit. With the development of semiconductor processes and the reduction of feature sizes, the advantages of the digital circuit are increasingly prominent. Compared with an analog circuit, the digital circuit has advantages of strong anti-interference capability, good portability, high integration, good testability, good programmability, a small layout area, low costs, and the like. As an important part of the digital RF transceiver, an all-digital phase-locked loop (PLL) (ADPLL) is used as a frequency synthesizer to generate a local oscillator signal, and performance of the ADPLL affects a signal-to-noise ratio of an entire transceiver link. Existing wireless communication, millimeter-wave RF transceivers, radar transceivers, and the like all have high requirements for the local oscillator signal. Especially in today's 5G and next-generation wireless communication systems, the generation of the local oscillator signal with high spectral purity and low phase noise is a breakthrough point and a challenge in technology, which requires the innovation of a phase-locked loop architecture and module innovation. With the progress of a complementary metal-oxide semiconductor (CMOS) process node, an analog phase-locked loop has encountered more and more technical bottlenecks, while a digital phase-locked loop has solved difficulties encountered by the analog phase-locked loop and has been increasingly favored. In the ADPLL, there are two key modules that determine the performance: one is a time-to-digital converter (TDC) and the other is a digital control oscillator. The TDC determines in-band phase noise performance of the ADPLL, while the digital control oscillator determines out-of-band phase noise performance of the ADPLL. Therefore, the breakthrough in the ADPLL performance is mainly reflected in the innovation of the TDC and the digital control oscillator.

A working principle of the TDC is to identify a phase difference between a feedback clock and a reference clock and convert the phase difference into a digital signal to be output. A resolution of the TDC determines an in-band phase noise level of the ADPLL. As the resolution is higher, an output frequency is more precise, and LO signal performance is better. A dynamic range of the TDC determines a maximum time interval that can be detected by the ADPLL. Linearity of the TDC determines a capability of the ADPLL to suppress spurs and jitter, which affects loop stability. The TDC is also widely used in other fields, such as physical measurement, laser ranging, communication, medical imaging, and the like.

The TDC has been developed for decades as a key module of the ADPLL. From analog TDCs to digital TDCs, the development transformation of the TDC reflects a continuous increase of the resolution and the continuous innovation of a TDC structure. Some TDC architectures that can achieve excellent performance have emerged in recent years, mainly including a single-chain delay line TDC, a Vernier TDC, a two-step TDC, a Stochastic TDC, and the like. The analog TDC has been abandoned due to a slow conversion speed, low stability, and a relatively complex structure, which is not conducive to integration. The single-chain delay line TDC (R. B. Staszewski, S. Vemulapalli, P. Vallur, J. Wallberg and P. T. Balsara, “Time-to-digital converter for RF frequency synthesis in 90 nm CMOS,” 2005 IEEE Radio Frequency Integrated Circuits (RFIC) Symposium-Digest of Papers, 2005, pp. 473-476.) is susceptible to changes in a process, voltage supply, and temperature (PVT), and a resolution is unable to achieve extremely high due to the limitations of a CMOS process and linearity. Therefore, such structure is rarely used for a high-resolution TDC. To further improve the resolution, the structure of the single-chain delay can be improved by disposing a double delay chain which is called a Vernier TDC (P. Dudek, S. Szczepanski and J. V. Hatfield, “A high-resolution CMOS time-to-digital converter utilizing a Vernier delay line,” in IEEE Journal of Solid-State Circuits, vol. 35, no. 2, pp. 240-247, February 2000.). Compared with the single-chain delay, a quantity of delay units is increased much to obtain the same dynamic range, resulting in an increase in power consumption and a layout area, and the resolution is still susceptible to the PVT variation. To solve a contradiction between the resolution and the dynamic range, the single-chain delay TDC and Vernier TDC can be combined to form a two-step TDC structure, where the single-chain delay TDC is coarsely quantized and the Vernier TDC is finely quantized. To achieve the conversion from coarse quantization to fine quantization, a shifting circuit is required. A time amplifier(TA)-based shifting TDC uses metastability of an SR latch to amplify a time interval, but inherently poor linearity degrades phase noise performance of the ADPLL (Chorng-Si Hwang, Poki Chen and Hen-Wai Tsao, “A high-precision time-to-digital converter using a two-stage conversion scheme,” in IEEE Transactions on Nuclear Science, vol. 51, no. 4, pp. 1349-1352, August 2004.). A bang-bang phase detector (BBPD) is popular due to low complexity and low power consumption, but its nonlinearity can easily cause the PLL to lose lock. An ADC-shifting-based TDC converts a time residual amount into a voltage amount, and then digitized by a minimal resolvable voltage of the ADC, but mismatching of a resistor and capacitor in an analog-intensive ADC deteriorates overall linearity of the TDC and generates spurs to in-band phase noise of the ADPLL, To further solve the contradiction between the resolution and the dynamic range and a problem of linearity deterioration caused by the two-step TDC shifting circuit, Vernier TDCs can be connected end-to-end to form a Vernier ring to make full use of delay units of the Vernier TDCs, which not only keeps a large dynamic range, but also achieves a high resolution, but still does not solve the problem that the resolution is easily affected by the PVT variation, and it is extremely difficult to maintain good linearity especially in the high resolution. Moreover, the structure has extremely strict requirements for matching a delay ring and layout wiring. A gated ring oscillator-based TDC and a derived TDC can achieve a single-picosecond or even sub-picosecond resolution by first-order or even multi-order shaping of noise, but is susceptible to the influence of ring oscillator noise and linearity of an integrator and a quantizer. Therefore, the linearity is not extremely good. A stochastic TDC (STDC) uses a time offset of a Gaussian distribution on a large quantity of identical comparators to parallelly evaluate a phase relationship between two input signals. However, the resolution depends on the quantity of comparators and a slope of the input signal, which greatly increases hardware overhead and power consumption, and is highly sensitive to PVT variation. Conventional STDCs use a linear input range to enhance linearity. However, this approach significantly reduces conversion efficiency. Although the conventional STDCs have a great capability to achieve an ultra-fine temporal resolution and good scalability on the order of picoseconds, high implementation complexity and low efficiency have always constrained the application of STDCs.

In summary, it is difficult for existing TDC technologies to achieve the sub-picosecond or even femtosecond-level resolution, and even if the sub-picosecond resolution can be achieved, the linear performance is extremely poor, and an additional linear calibration technology is required, which increases a difficulty and complexity of implementation. A reason for this is a limited time-delay resolution due to the CMOS process and susceptibility to the PVT variation. To break through the limitations of the CMOS process, a passive transmission line technology can be applied to the TDC technology to achieve an ultra-high delay resolution through transmission line matching. Since passive circuits are less sensitive to the influence of the PVT variation, they effectively overcome the shortcomings of active CMOS technology, to achieve a breakthrough in the TDC resolution, and to meet strict requirements for an ultra-low phase noise local oscillator signal in next generation wireless communication technology.

### SUMMARY

The present invention is intended to provide a time-to-digital converter with a sub-100 fs resolution and based on a transmission line structure, achieving an ultra-high resolution, being less sensitive to PVT variations, and utilizing TDC structure.

The present invention is implemented by at least one of the following technical solutions.

A time-to-digital converter with a sub-100 fs resolution and based on a transmission line structure, including three-stage time-to-digital converters (TDC) configured to identify a decimal phase difference between a reference clock signal FREF and a feedback signal CKV after phase-locked loop frequency division, where the three-stage TDCs are connected in parallel; and each stage of the TDCs disposed a plurality of delay units. The delay units are connected to a locking detector by which to determine an output result of each stage for performing locking.

Further, a first-stage TDC employs a single-chain delay TDC structure and includes a plurality of buffer delay units connected in series, each buffer delay unit includes two CMOS inverters, and the two CMOS inverters are connected in series; the feedback signal CKV after phase-locked loop frequency division is transmitted in a single-chain delay chain, an output end of each buffer delay unit is connected to one input end of a comparator, and the other input end of the comparator is connected to the reference clock signal FREF, to compare a sequence of rising edges of two input signals, thereby producing a comparison result, i.e., a temperature code; and the temperature code is fed to the locking detector for lock determination, and when outputs of the comparators are all the same or less than a set value, the locking detector turns off the first-stage TDC and enters a second-stage TDC.

Further, the second-stage TDC employs a double-chain delay TDC structure and includes a plurality of buffer delay units and a plurality of comparators, the plurality of buffer delay units are connected in series to form two transmission chains, one inputs the feedback signal CKV after phase-locked loop frequency division, and the other inputs the reference clock signal FREF; and an output end of each buffer delay unit is connected to an input end of a comparator, where each comparator inputs different kinds of signals to compare a sequence of rising edges of two input signals, thereby producing a comparison result, i.e., a temperature code; after a first-stage TDC is locked, the first-stage TDC continues to discern a residual phase difference between different signals, and when outputs of the comparators are all the same or less than a set value, outputs of the second-stage TDC is frozen, the second-stage TDC is turned off, and determining of a third-stage TDC is initiated.

Further, the third-stage TDC includes two transmission lines, an input end of each transmission line is connected to a buffer, where one transmission line is a linear microstrip line structure that is spliced end-to-end by a plurality of metal cuboids; the other transmission line employs a S-type microstrip line structure, that is, a delay unit is a bent semi-octagonal body, each semi-octagonal body is connected end-to-end to form a long transmission line chain, the CKV signal enters the S-type microstrip line to be transmitted, and the FREF signal enters the linear microstrip line to be transmitted.

The comparators are connected across terminals of each delay unit of the two signal transmission chains to compare a sequence of rising edges of two input signals, thus outputting a comparison result.

Further, a comparator of the third-stage TDC employs a Strong adaptive regeneration mechanism (ARM) flip-flop structure, and a characteristic delay of the transmission line is equal to a square root value of a product of a unit inductance and a unit capacitance.

Further, an adjustable capacitor is connected to an end of each stage of the TDC and is controlled by an external digital-to-analog converter (DAC) circuit.

Further, an end of each transmission line of the third-stage TDC connects to a resistor fabricated using Taiwan semiconductor manufacturing company (TSMC) 40 nm general purpose (GP) process.

Further, an N-channel metal-oxide-semiconductor (NMOS) transistor operating in linear region is connected to an end of the resistor to achieve mismatched resistor compensation, with the NMOS transistor controlled by an external DAC.

Further, each stage of the TDC includes 32 comparators.

Further, the three-stage TDCs are executed in parallel, with two input signals first entering the first-stage TDC for quantization, and when a difference between a maximum value and a minimum value output by the TDC is less than 2, the first-stage TDC is locked; then determining a next-stage TDC is performed, with the locking criteria being the same as that of the first-stage TDC, and a phase difference between two signals gradually decreases with the locking of a PLL, which means phase difference alignment is performed, and the PLL completes the locking.

Compared with the prior art, the present invention has the following beneficial effects.
(1) In the present invention, the transmission line structure is applied in the design of TDC for the first time, and a TDC resolution of 100 fs is achieved for the first time, which is the highest resolution TDC structure published. As a result, applying the transmission line structure to ADPLL achieves a local oscillator signal source with ultra-low in-band phase noise performance, which can be applied for 5G and 6G communication systems with stringent requirements for local oscillator signals.
(2) Compared to an active CMOS process, the TDC based on transmission line structure of the present invention is less sensitive to PVT variation, thus having good linearity, saving large area of complex linear calibration circuits, making the implementation of high-resolution TDC simpler and more feasible, and also saving power consumption and costs.
(3) In the present invention, a structure of multi-stage TDCs is employed, to achieve the high resolution while having a large dynamic range to cover one cycle of the input signals. Compared to the multi-stage TDCs based on TA or ADC shifting, a locking detector-based shifting technology implemented digitally is applied in the present invention, to prevent introducing additional noise and deteriorating the linearity of the TDC, making it possible to achieve high-resolution TDC while providing good linearity.

### BRIEF DESCRIPTION OF THE DRAWINGS

Embodiments of the present invention are described in detail in conjunction with accompanying drawings, so that the above and other purposes, features and advantages of the present invention become clearer. Where,

FIG. 1 is an overall architecture diagram of time-to-digital converters with a sub-100 fs resolution and based on a transmission line structure according to an embodiment of the present invention;

FIG. 2 is a structural diagram of a first-stage TDC according to an embodiment of the present invention;

FIG. 3 is a structural diagram of a second-stage TDC according to an embodiment of the present invention;

FIG. 4 is a structural diagram of a third-stage TDC according to an embodiment of the present invention;

FIG. 5 is a structural diagram of a TL in electromagnetic field simulation according to an embodiment of the present invention; and

FIG. 6 is a layout diagram of the third-stage TDC according to an embodiment of the present invention.

### DETAILED DESCRIPTION OF THE EMBODIMENTS

The following clearly and completely describes technical solutions in embodiments of the present invention with reference to accompanying drawings in the embodiments of the present invention. Apparently, the described embodiments are merely some but not all of the embodiments of the present invention.

### Embodiment 1

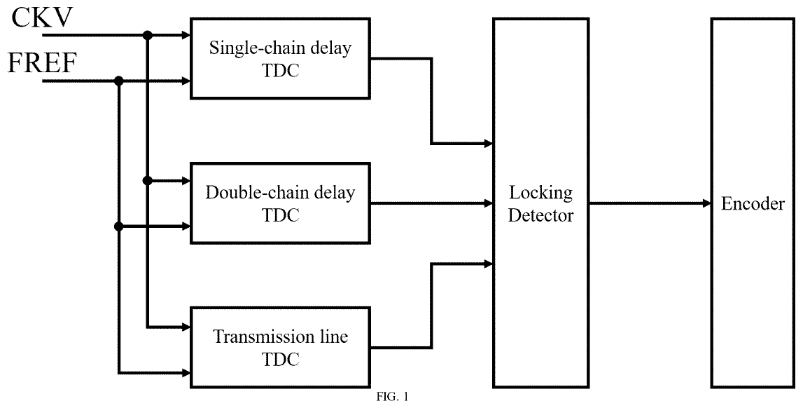

As shown in FIG. 1, a time-to-digital converter with a sub-100 fs resolution and based on a transmission line structure in this embodiment, applied to the design of an all-digital phase-locked loop with high-resolution and low in-band phase noise performance to identify a decimal phase difference between a reference clock signal FREF and a feedback signal CKV after phase-locked loop frequency division, includes three-stage time-to-digital converters (TDCs), with the three-stage TDCs connected in parallel and operating in parallel, without direct interconnections among each stage. A plurality of delay units are disposed for each stage of the TDC, an output end of each delay unit is connected to an input end of a comparator, and an output result of the comparator is used to determine whether to perform determining a next-stage TDC.

The reference clock signal (FREF) and the feedback signal (CKV) after the phase-locked loop frequency division first enter a first-stage TDC for quantization. Based on the output result of the comparator, a locking detector determines that the first-stage TDC is locked, an output of the same is frozen, and the first-stage TDC can be turned off after freezing to save power consumption. Then the determination of a next-stage TDC is performed with the locking criteria being the same as that of the first-stage TDC, and a phase difference between two signals gradually decreases with the locking of a phase-locked loop, which means phase difference alignment is performed, and the phase-locked loop completes the locking. After locking, a difference between a maximum value and a minimum value of a temperature code output by each stage of the TDC is less than 2, until changes in external environment (temperature, power supply voltage, and process variations) cause the phase-locked loop to lose lock and the phase difference between the FREF and the CKV is no longer aligned, then the TDC is reactivated, a new phase difference is tracked, and identification of decimal phase difference between an FREF signal and a CKV signal is started.

As a preferred embodiment, the first-stage TDC is implemented using a single-chain delay TDC with 32 delay units, to provide a resolution of 25 ps and a dynamic range of approximately 800 ps, which is sufficient to cover a cycle of an input signal (1.75 GHz), and a 5-bits output is finally implemented.

A second-stage TDC is a TDC structure with a Vernier delay chain and is provided with 32 delay units, to provide a resolution of 1.6 ps and a dynamic range of approximately 51 ps, which is sufficient to cover 1 LSB range of the first-stage TDC, and a 5-bits output is finally implemented.

A third-stage TDC is a Vernier transmission line TDC and is provided with 32 delay units, to provide a resolution of 100 fs and a dynamic range of 3.2 ps, which is sufficient to cover 1 LSB range of the second-stage TDC, and a 5-bits output is finally implemented.

FIG. 1 is an overall architecture diagram of all TDCs according to an embodiment of the present invention, where two input signals enter the three-stage TDCs in parallel for phase difference quantization. 32 delay units are disposed for each stage of the TDC, that is, a comparator outputs 32 temperature codes which are then fed into the locking detector for lock determination and are converted into 5-bit binary values by an encoder to be output, and the three-stage TDCs output a total of 15-bit phase difference information.

The working principle is as follows: when the phase difference between two input signals is greater than 1 LSB of the first-stage TDC, the first-stage TDC starts to operate, meanwhile the locking detector detects the temperature code output by the first-stage TDC in consecutive several cycles of a phase-locked loop feedback signal CKV, that is, taking a maximum value and a minimum value of the temperature code converted into decimal values and converting into 5-bits binary values by the encoder for output. When the locking detector detects that a difference between the maximum value and the minimum value of the temperature code is less than 2 or “0” in last several CKV cycles, the first-stage TDC is determined to be locked, and the output of the first-stage TDC is frozen. If the conditions are not met, detection will continue because it means that the phase-locked loop has not locked and the TDC keeps working. As the PLL (phase-locked loop) locks, the phase difference between the two input signals is less than 1 LSB of the first-stage TDC, and the second-stage TDC starts lock determination, which is similar to the lock determination for the first-stage TDC, until the entire PLL completes the lock, and the phase difference between the two input signals is approximate to a resolution range of the third-stage TDC.

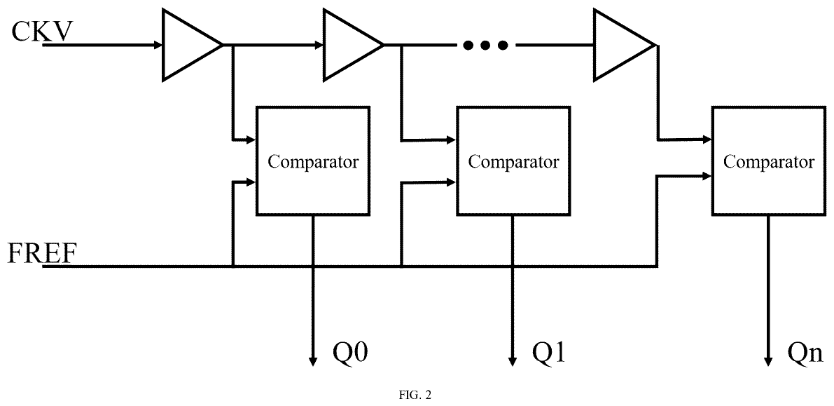

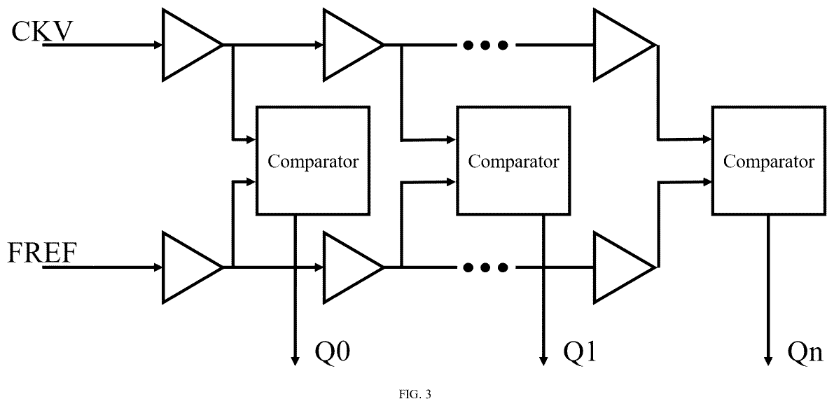

As shown in FIG. 2, the first-stage TDC employs a single-chain delay TDC structure, which includes several buffer delay units and several comparators, where the buffer delay unit includes two CMOS inverters which are connected in series. The several buffer delay units are connected in series, and an output of each buffer delay unit is connected to one comparator, one end of the comparator is connected to a CKV signal (feedback signal after PLL frequency division) transmission chain, and the other end is connected to an FREF signal (reference clock signal) transmission chain, to compare the sequence of rising edges of two input signals. When the CKV's arrives before the FREF's, the comparator outputs “1”, and conversely outputs “0”. Therefore, the comparator always outputs a string of “1”s followed by a string of “0”s, which greatly facilitates the detection of the phase difference and the locking determination. The first-stage TDC requires a 5-bit output result by the comparator, thus requiring 32 buffer delay units and 32 comparator units. The resolution of the TDC depends on the delay of one single buffer delay unit, and is approximately 25 ps through post-layout simulation, thus covering a dynamic range of approximately 800 ps. The 32 temperature codes output by the comparators indicate the phase difference information between the CKV and the FREF, that is, when an N^{th} comparator unit outputs a “1” temperature code and an (N+1)^{th} comparator unit outputs a “0” temperature code, the phase difference between the CKV and the FREF is the time for N resolutions. The 32 temperature codes output by the comparators are fed into the locking detector for the lock determination. With the locking by the PLL, the CKV is gradually approximate to the FREF signal until the phase difference between both is less than 1 LSB. In this case, when a first-stage comparator outputs all “0”s or steadily fluctuates between two numbers (with the difference between a maximum value and a minimum value being less than 2), the locking detector determines that the first-stage TDC has been locked, thus determining whether to freeze the output from the first-stage TDC, performing lock determination for the second-stage TDC, and shutting down the first-stage TDC to reduce power consumption.

The structure of the second-stage TDC is similar to that of the first-stage TDC, expect that an additional buffer delay chain is added to an FREF signal transmission chain, and at this point, the resolution of the TDC no longer depends on the delay of a single buffer unit, but on the time difference between the two buffer delays, thus improving the resolution of the second-stage TDC. A buffer transmission chain where the CKV is located is a “slow chain”, that is, a buffer delay is relatively larger, while a buffer delay chain where the FREF is located is a “fast chain”, that is, a buffer delay is relatively smaller. The 32 comparators are connected across output ends of buffer units of the two signal transmission chains respectively, to compare a sequence of rising edges of two input signals, thus outputting a comparison result (“0” or “1”). The second-stage TDC has a resolution of approximately 1.6 ps, thus covering a dynamic range of 51 ps. A function of which is to continue to identify a residual phase difference between the FREF signal and the CKV signal after the first-stage TDC is locked (after the first-stage TDC is locked, the phase difference between the FREF and the CKV is approximate to one LSB range of 25 ps by feedback through the PLL, thus detectable by the second-stage TDC). The second-stage TDC also outputs 32 temperature codes indicating the phase difference information between the FREF signal and the CKV signal. The 32 temperature codes are fed into the locking detector for locking determination. When the temperature codes are all “0”s or steadily fluctuates between two numbers (with the difference between a maximum value and a minimum value being less than 2), it is determined as locked, and then the lock determination for the third-stage TDC is performed. An output from the second-stage TDC is frozen, and the second-stage TDC is shut down to reduce power consumption.

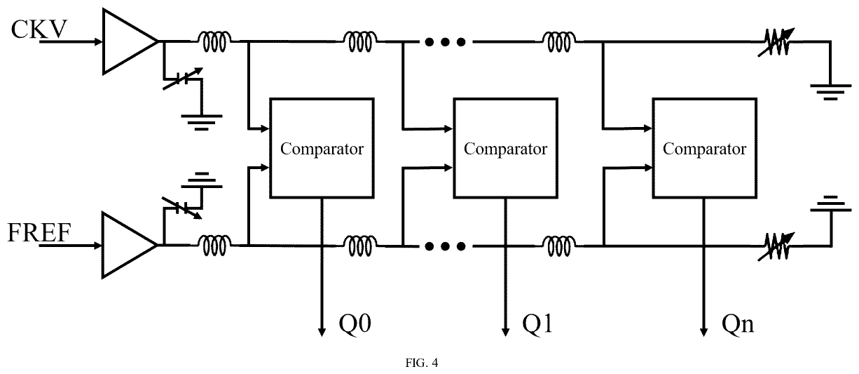

As shown in FIG. 4, the third-stage TDC includes two stages of driving buffer formed in series by two inverters to drive two transmission lines. The two transmission lines are implemented by the thickest layer of metal in a TSMC40nmGP 1P10M process, thereby reducing transmission line loss. One of the transmission line employs a linear microstrip line structure, namely, a “fast chain” transmission line with its metal shape being a long rectangular chain spliced by small sections of small cuboids (i.e., delay units) end-to-end. There are two traces perpendicular to the transmission delay line formed respectively at the beginning and the end of each delay unit, and the two traces are for connecting to input ends of the comparator layout implemented by lower layer of metal. The other transmission line has an S-shaped microstrip line structure, namely, a “slow chain” transmission line, that is, a delay unit of the other transmission line is a bent semi-octagonal body, and each S-type delay unit is connected end-to-end to form a long transmission line chain. Similarly, there are two traces perpendicular to the transmission line formed respectively at the beginning and the end of each delay unit, and the two traces are for connecting to the other input end of the comparator layout implemented by lower layer of metal. The CKV signal enters the “S”-shaped structure for transmission, and the FREF signal enters the linear structure for transmission. The resolution of the TDC is a time difference between the “S”-shaped delay unit and the linear transmission line delay unit, which is approximately 100 fs in electromagnetic field (EM) simulation. The 32 comparators are connected across the outputs of each delay unit on the two signal transmission chains to compare a sequence of rising edges of the two input signals, thereby outputting a comparison result (“0” or “1”). The 32 comparators implement a 5-bit output and employ Strong ARM flip-flop structures. An input tube of a proper size and a transmission line delay unit of a proper size are selected based on the electromagnetic field simulation result of transmission line's intrinsic delay, to reduce a load capacitance and unit inductance of the transmission line, thereby achieving low intrinsic delay and high resolution. The comparator layout is carefully arranged to reduce the effect of mismatch. Post-comparator simulation and Monte Carlo simulation indicate that the comparator can identify a phase error of 100 fs. According to a transmission line theory and its equivalent model, each delay unit on the transmission line can be equivalent to a section of unit inductance, and an equivalent capacitance seen from the input end of the comparator is a load capacitance (fan-in capacitance) of the transmission line, and a characteristic delay must be extremely small to achieve a high-resolution TDC. An input tube of a proper size and a transmission line delay unit of a proper size are selected based on the electromagnetic field simulation result of the transmission line's intrinsic delay, to reduce a load capacitance and unit inductance of the transmission line, thereby achieving low intrinsic delay and high resolution.

In addition, to reduce mismatch between the two driving stages (i.e., buffers formed by two inverters in series), an adjustable capacitor is connected at the end of each driver stage and controlled by an external DAC circuit. At the end of the transmission line, a resistor with TSMC40nm GP process is used for transmission line matching. To reduce the influence of resistor mismatching, an NMOS transistor operating in a linear region is connected at the end of the resistor to compensate for mismatched resistance, with a gate connected to an external DAC for controlling to implement adjustment of the resistance of the MOS transistor, preventing mismatching between a characteristic impedance of the transmission line and a load impedance caused by process deviation. After a chip is manufactured, the chip calibrates the characteristic impedance and the load impedance of the transmission line to be equal to reduce the effect of PVT variation on the transmission line matching. The temperature codes output from the 32 comparators are fed into the locking detector for lock determination, thereby achieving a final lock.

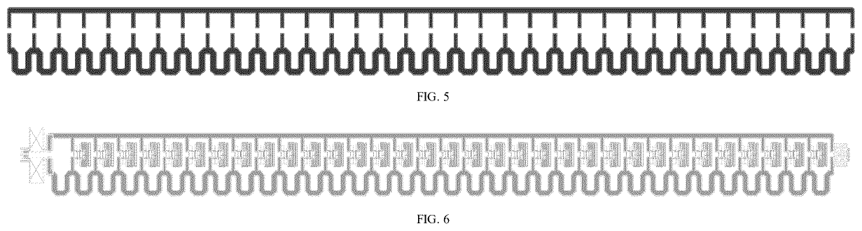

A structure diagram of a transmission line TDC (TL-TDC) in electromagnetic field (EM) simulation is shown in FIG. 5, where the influence of a variable capacitance at an input end and a variable resistance at an output end on the TL is considered. A layout diagram is shown in FIG. 6, where the entire TDC is implemented in the TSMC CMOS 40 nm GP process. with the third layer, the fourth layer, and the fifth layer of metal are paved, and the first and the second layer of metal are used as power cables and output data traces of the comparators, and the transmission line (TL) is implemented with the thickest layer of metal M10, thus shielding the influence of a complicated metal trace on the TL, and the thickest layer of metal reduces a parasitic resistance and loss of the TL. EM simulation shows that the TL-TDC achieves a resolution of up to 100 fs, which is the highest reported resolution for a TDC structure.

To achieve quantization from the first-stage TDC to the second-stage TDC then to the third-stage TDC, a locking detector-based shifting technology implemented digitally is used. The three-stage TDCs are executed in parallel, and two input signals firstly enter the first-stage TDC for quantization. When an output of the TDC changes slightly in a plurality of consecutive identical cycles, that is, a difference between a maximum value and a minimum value of the output is less than 2, it can be determined that the first-stage TDC has been locked, and the output is frozen. Then determining a next-stage TDC is performed, determining of locking is the same as for the first-stage TDC, and a phase difference between two signals gradually decreases with the locking of a PLL, which means phase difference alignment is performed, and the PLL completes the locking. Digitally implemented shifting introduces much less noise compared with TA-based or ADC-based shifting, and the linearity of the TDC is better, which helps implementation of a high-resolution and high-linearity TDC in the present invention.

The above disclosed preferred embodiments of the present invention are only intended to assist in the explanation of the present invention. The preferred embodiments do not describe all details exhaustively, nor do they limit the present invention to the specific implementations described. Clearly, many modifications and variations can be made based on the content of this specification. The embodiments selected and specifically described in this specification are intended to better explain the principle and practical applications of the present invention, so that those skilled in the art can fully understand and utilize the present invention. The present invention is only limited by the claims, an entire scope, and equivalents thereof.

What is claimed is:

1. A time-to-digital converter with a sub-100 fs resolution and based on a transmission line structure, comprising three-stage time-to-digital converters (TDCs) configured to identify a decimal phase difference between a reference clock signal FREF and a feedback signal CKV after a phase-locked loop frequency division, wherein the three-stage TDCs are connected in parallel; each stage of the three-stage TDCs is disposed a plurality of delay units; and the plurality of delay units are connected to a locking detector, wherein an output result of each stage of the three-stage TDCs is determined by the locking detector for performing locking.

2. The time-to-digital converter according to claim 1, wherein a first-stage TDC employs a single-chain delay TDC structure and comprises a plurality of buffer delay units connected in series, each of the plurality of buffer delay units comprises two complementary metal-oxide-semiconductor (CMOS) inverters, and the two CMOS inverters are connected in series; the feedback signal CKV after the phase-locked loop frequency division is transmitted in a single-chain delay chain, an output end of each of the plurality of buffer delay units is connected to a first input end of a comparator, and a second input end of the comparator is connected to the reference clock signal FREF, to compare a sequence of rising edges of two input signals, wherein a comparison result comprising a temperature code is produced; and the temperature code is fed to the locking detector for a lock determination, and when outputs of the comparators are all the same or less than a set value, the locking detector turns off the first-stage TDC and enters a second-stage TDC.

3. The time-to-digital converter according to claim 1, wherein a second-stage TDC employs a double-chain delay TDC structure and comprises a plurality of buffer delay units and a plurality of comparators, the plurality of buffer delay units are connected in series to form two transmission chains, a first transmission chain inputs the feedback signal CKV after the phase-locked loop frequency division, and a second transmission chain inputs the reference clock signal FREF; and an output end of each of the plurality of buffer delay units is connected to an input end of each of the plurality of comparators, wherein each of the plurality of comparators inputs different kinds of signals to compare a sequence of rising edges of two input signals, a comparison result comprising a temperature code is produced; and after a first-stage TDC is locked, the first-stage TDC continues to discern a residual phase difference between the different kinds of signals, and when outputs of the plurality of comparators are all the same or less than a set value, outputs of the second-stage TDC is frozen, the second-stage TDC is turned off, and determining of a third-stage TDC is initiated.

4. The time-to-digital converter according to claim 1, wherein a third-stage TDC comprises two transmission lines, an input end of each of the two transmission lines is connected to a buffer, wherein a first transmission line is a linear microstrip line structure, wherein the linear microstrip line structure is spliced end-to-end by a plurality of metal cuboids; a second transmission line employs a S-type microstrip line structure, that is, each of the plurality of delay units is a bent semi-octagonal body, each bent semi-octagonal body is connected end-to-end to form a long transmission line chain, the feedback signal CKV enters the S-type microstrip line structure to be transmitted, and the reference clock signal FREF enters the linear microstrip line structure to be transmitted; and comparators are connected across outputs of each of the plurality of delay units of two signal transmission chains to compare a sequence of rising edges of two input signals, thus outputting a comparison result.

5. The time-to-digital converter according to claim 4, wherein a comparator of the third-stage TDC employs a Strong adaptive regeneration mechanism (ARM) flip-flop structure, and a characteristic delay of the two transmission lines is equal to a square root value of a product of a unit inductance and a unit capacitance.

6. The time-to-digital converter according to claim 4, wherein an adjustable capacitor is connected to an end of each stage of the three-stage TDCs and is controlled by an external digital-to-analog converter (DAC) circuit.

7. The time-to-digital converter according to claim 4, wherein an end of each of the two transmission lines of the third-stage TDC connects to a resistor fabricated using Taiwan semiconductor manufacturing company (TSMC) 40 nm general purpose (GP) process.

8. The time-to-digital converter according to claim 7, wherein an N-channel metal-oxide semiconductor (NMOS) transistor operating in a linear region is connected to an end of the resistor to achieve a compensation of a mismatched resistor, with the NMOS transistor controlled by an external DAC.

9. The time-to-digital converter according to claim 1, wherein each stage of the three-stage TDCs comprises 32 comparators.

10. The time-to-digital converter according to claim 1, wherein the three-stage TDCs are executed in parallel, with two input signals first entering a first-stage TDC for quantization, and when a difference between a maximum value and a minimum value output by the first-stage TDC is less than 2, the first-stage TDC is locked; determining that a next-stage TDC is performed, with a locking criteria being the same as a locking criteria of the first-stage TDC, and a phase difference between two signals gradually decreases with a locking of a phase-locked loop (PLL), which means a phase difference alignment is performed, and the PLL completes the locking.

11. The time-to-digital converter according to claim 2, wherein each stage of the three-stage TDCs comprises 32 comparators.

12. The time-to-digital converter according to claim 3, wherein each stage of the three-stage TDCs comprises 32 comparators.

13. The time-to-digital converter according to claim 4, wherein each stage of the three-stage TDCs comprises 32 comparators.

14. The time-to-digital converter according to claim 5, wherein each stage of the three-stage TDCs comprises 32 comparators.

15. The time-to-digital converter according to claim 6, wherein each stage of the three-stage TDCs comprises 32 comparators.

16. The time-to-digital converter according to claim 7, wherein each stage of the three-stage TDCs comprises 32 comparators.

17. The time-to-digital converter according to claim 8, wherein each stage of the three-stage TDCs comprises 32 comparators.
